(19) United States
(12) Patent Application Publication
(10) Pub. No.: US 2025/0386500 A1
(43) Pub. Date: Dec. 18, 2025

(54) SEMICONDUCTOR MEMORY DEVICE, ELECTRONIC SYSTEM AND METHOD FOR MANUFACTURING SEMICONDUCTOR MEMORY DEVICE

(71) Applicant: Samsung Electronics Co., Ltd., Suwon-si (KR)

(72) Inventors: Namsoo KIM, Suwon-si (KR); Ji-Hoon CHOI, Suwon-si (KR); Hyung Joon KIM, Suwon-si (KR)

(73) Assignee: Samsung Electronics Co., Ltd., Suwon-si (KR)

(21) Appl. No.: 18/985,244

(22) Filed: Dec. 18, 2024

(30) Foreign Application Priority Data
Jun. 12, 2024 (KR) 10-2024-0076208

(51) Int. Cl. H10B 43/27; H10B 43/10; H10B 43/35; H10B 43/40

(52) U.S. Cl. CPC H10B 43/27; H10B 43/10; H10B 43/35; H10B 43/40

(57) ABSTRACT

A semiconductor memory device includes a substrate, a mold structure stacked on the substrate in a first direction, a first channel structure penetrating through the mold structure and extending in the first direction, the first channel structure including a first semiconductor pattern, a channel pad connected to the first semiconductor pattern, and an information storage film between the first semiconductor pattern and the plurality of gate electrodes, an upper insulating layer on the mold structure, a select gate electrode on the upper insulating layer, and a second channel structure penetrating through the select gate electrode and the upper insulating layer and connected to the first channel structure, wherein the second channel structure includes a second semiconductor pattern electrically connected to the channel pad and a liner film along an outer side surface of the second semiconductor pattern.

### CROSS-REFERENCE TO RELATED APPLICATIONS

This application claims priority to Korean Patent Application No. 10-2024-0076208, filed in the Korean Intellectual Property Office on Jun. 12, 2024, the entire contents of which are hereby incorporated by reference.

### BACKGROUND

### Field

The present disclosure relates to semiconductor memory devices, electronic systems, and methods for manufacturing the semiconductor memory device.

### Description of Related Art

There is a need for a semiconductor memory device capable of storing higher-capacity data in an electronic system that requires data storage. Accordingly, ways to increase the data storage capacity of the semiconductor memory devices are being studied. For example, as one of the methods for increasing the data storage capacity of the semiconductor device, a semiconductor device including three-dimensional arrangement of memory cells instead of two-dimensional arrangement of memory cells has been proposed.

### SUMMARY

In order to solve one or more problems (e.g., the problems described above and/or other problems not explicitly described herein), the present disclosure provides semiconductor memory devices with improved electrical characteristics and/or reliability.

In order to solve one or more problems (e.g., the problems described above and/or other problems not explicitly described herein), the present disclosure also provides electronic systems with improved electrical characteristics and/or reliability.

In order to solve one or more problems (e.g., the problems described above and/or other problems not explicitly described herein), the present disclosure also provides methods for manufacturing a semiconductor memory device with improved electrical characteristics and/or reliability.

According to some example embodiments of the present disclosure, the liner film can be disposed on an outer side surface of the second semiconductor pattern to mitigate or prevent oxidation of the second semiconductor pattern. Accordingly, reliability of the semiconductor memory device can be improved.

According to some example embodiments of the present disclosure, using the second etching process, spacers can be selectively removed, while not substantially removing the channel pads. Accordingly, electrical characteristics of the semiconductor memory device can be improved.

According to some example embodiments of the present disclosure, the second etching process and the process of forming the liner film can be performed by an in-situ method to mitigate or prevent an oxide layer from being formed on the channel pad.

According to an example embodiment of the present disclosure, a semiconductor memory device includes a substrate, a mold structure including a plurality of mold insulating layers and a plurality of gate electrodes, the plurality of mold insulating layers and the plurality of gate electrodes being alternately stacked on top of each other on the substrate in a first direction, a first channel structure penetrating through the mold structure and extending in the first direction, the first channel structure including a first semiconductor pattern, a channel pad connected to the first semiconductor pattern, and an information storage film between the first semiconductor pattern and the plurality of gate electrodes, an upper insulating layer on the mold structure, a select gate electrode on the upper insulating layer, and a second channel structure penetrating through the select gate electrode and the upper insulating layer, the second channel structure connected to the first channel structure, wherein the second channel structure includes a second semiconductor pattern electrically connected to the channel pad, a dielectric pattern between the second semiconductor pattern and the select gate electrode, and a liner film along an outer side surface of the second semiconductor pattern.

According to an example embodiment of the present disclosure, a semiconductor memory device includes a peripheral circuit structure and a cell structure stacked on the peripheral circuit structure, wherein the cell structure includes a substrate, a mold structure including a plurality of mold insulating layers and a plurality of gate electrodes, the plurality of mold insulating layers and the plurality of gate electrodes being alternately stacked on top of each other on the substrate in a first direction, a first channel structure penetrating through the mold structure and extending in the first direction, the first channel structure including a first semiconductor pattern, a channel pad on the first semiconductor pattern, and an information storage film between the first semiconductor pattern and the plurality of gate electrodes, an upper insulating layer on the mold structure, a select gate electrode on the upper insulating layer, a second channel structure penetrating through the select gate electrode and the upper insulating layer, the second channel structure connected to the first channel structure, a bit line plug connected to the second channel structure, and a bit line connected to the bit line plug and extending in a second direction, the second direction being a horizontal direction intersecting the first direction, and the second channel structure includes a second semiconductor pattern electrically connected to the channel pad, a dielectric pattern between the second semiconductor pattern and the select gate electrode, and a liner film along an outer side surface of the second semiconductor pattern.

According to an example embodiment of the present disclosure, an electronic system includes a main substrate, a semiconductor memory device on the main substrate, the semiconductor memory device including a peripheral circuit structure and a cell structure stacked on the peripheral circuit structure, and a controller on the main substrate and electrically connected to the semiconductor memory device, wherein the cell structure includes a substrate, a mold structure including a plurality of mold insulating layers and a plurality of gate electrodes, the plurality of mold insulating layers and the plurality of gate electrodes being alternately stacked on top of each other on the substrate in a first direction, a first channel structure penetrating through the mold structure and extending in the first direction, the first channel structure including a first semiconductor pattern, a channel pad on the first semiconductor pattern, and an information storage film between the first semiconductor pattern and the plurality of gate electrodes, an upper insulating layer on the mold structure, a select gate electrode on the upper insulating layer, and a second channel structure penetrating through the select gate electrode and the upper insulating layer, the second channel structure connected to the first channel structure, and the second channel structure includes a second semiconductor pattern electrically connected to the channel pad, a dielectric pattern between the second semiconductor pattern and the select gate electrode, and a liner film along an outer side surface of the second semiconductor pattern.

According to an example embodiment of the present disclosure, a method for manufacturing semiconductor memory device includes stacking a sacrificial insulating layer, an upper insulating layer, and a select gate electrode in order on a mold structure and a channel structure, the channel structure including a channel pad in contact with the sacrificial insulating layer, forming a first through hole penetrating through the upper insulating layer, the select gate electrode, and an upper surface of the sacrificial insulating layer in a first direction, forming a dielectric pattern along a side and a bottom of the first through hole, forming a spacer along an inner side surface of the dielectric pattern, removing a bottom portion of the spacer, the sacrificial insulating layer, and a portion of the channel pad to form a second through hole, the second through hole exposing a side of the sacrificial insulating layer and the channel pad, removing the spacer using a selective etching process, forming a liner film on the inner side surface of the dielectric pattern, the side of the sacrificial insulating layer, and the portion of the channel pad, and forming a semiconductor pattern on the liner film.

### BRIEF DESCRIPTION OF THE DRAWINGS

The above and other aspects and features of the present disclosure will become more apparent by describing in detail some example embodiments thereof with reference to the attached drawings, in which:

FIG. 1 is a plan view provided to explain a semiconductor memory device according to an example embodiment;

FIG. 2 is a cross-sectional view taken along line A-A of FIG. 1;

FIG. 3 is an enlarged view provided to explain the region Q1 of FIG. 2;

FIG. 4 is an enlarged view provided to explain the region Q2 of FIG. 2;

FIG. 5 is a cross-sectional view taken along line B-B of FIG. 4;

FIG. 6 is a diagram provided to explain a semiconductor memory device according to an example embodiment;

FIG. 7 is a diagram provided to explain a semiconductor memory device according to an example embodiment;

FIG. 8 is a diagram provided to explain a semiconductor memory device according to an example embodiment;

FIG. 9 is a diagram provided to explain a semiconductor memory device according to an example embodiment;

FIG. 10 is an enlarged view provided to explain the region Q3 of FIG. 9;

FIG. 11 is a diagram provided to explain a semiconductor memory device according to an example embodiment;

FIG. 12 is a diagram provided to explain a semiconductor memory device according to an example embodiment;

FIG. 13 is a diagram provided to explain a semiconductor memory device according to an example embodiment;

FIGS. 14 to 22 are diagrams showing intermediate stages, provided to explain a method for manufacturing a semiconductor memory device according to an example embodiment;

FIG. 23 is a flowchart provided to explain a method for manufacturing a semiconductor memory device according to an example embodiment;

FIG. 24 is an example block diagram provided to explain an electronic system according to an example embodiment;

FIG. 25 is an example perspective view illustrating an electronic system including a semiconductor memory device according to an example embodiment;

FIG. 26 is a schematic cross-sectional view taken along line V-V of FIG. 25.

### DETAILED DESCRIPTION

As used herein, expressions such as “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

Hereinafter, semiconductor memory devices and methods for manufacturing the same according to some example embodiments will be described in detail with reference to the drawings.

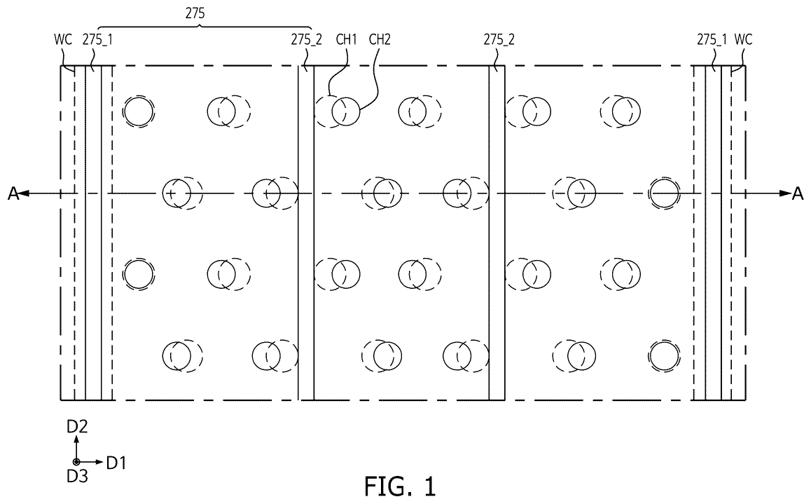

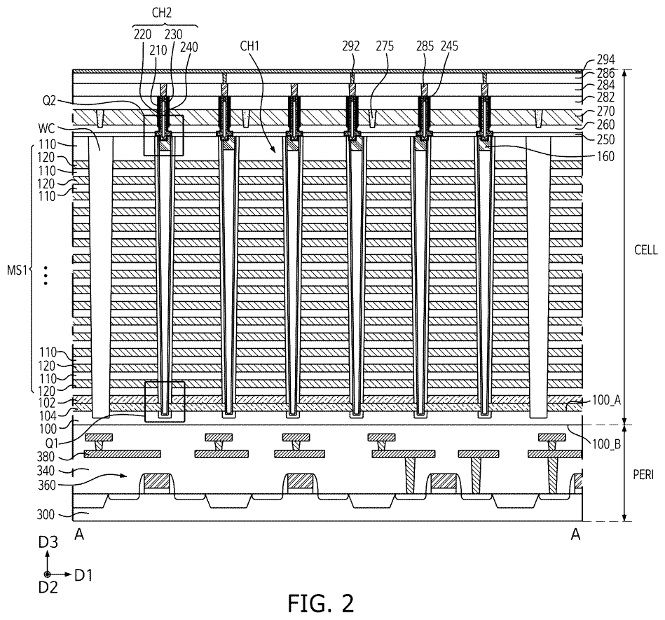

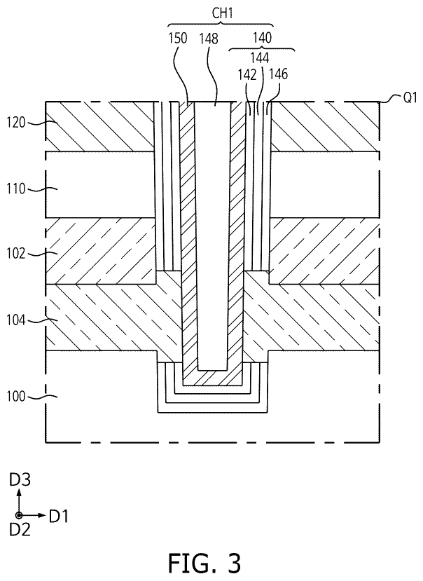

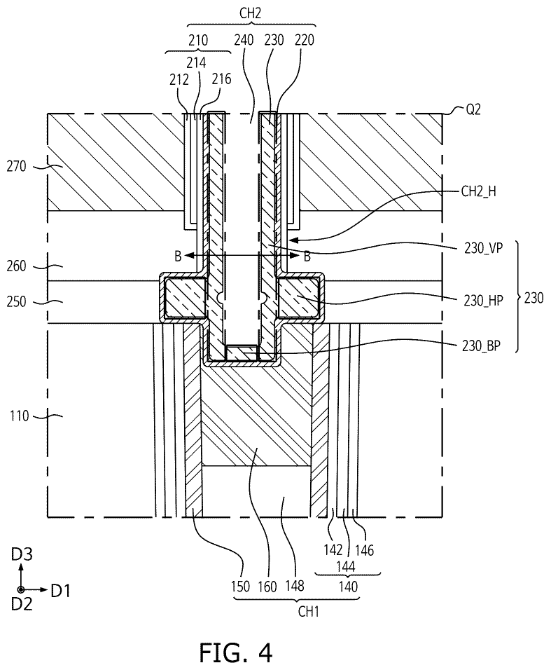

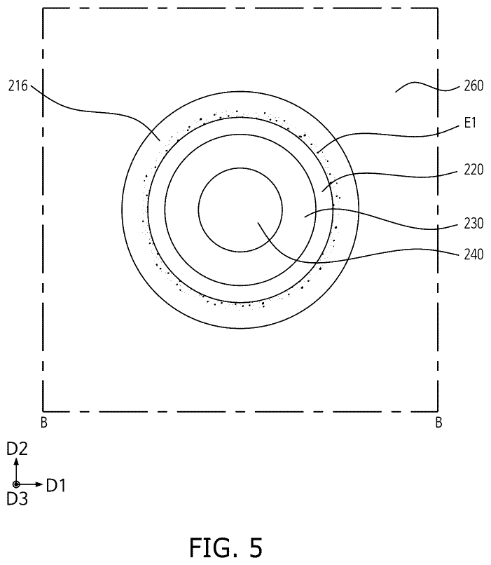

FIG. 1 is a plan view provided to explain a semiconductor memory device according to an example embodiment. FIG. 2 is a cross-sectional view taken along line A-A of FIG. 1. FIG. 3 is an enlarged view provided to explain the region Q1 of FIG. 2. FIG. 4 is an enlarged view provided to explain the region Q2 of FIG. 2. FIG. 5 is a cross-sectional view taken along line B-B of FIG. 4.

Referring to FIGS. 1 to 5, a semiconductor memory device according to an example embodiment may include a cell structure CELL and a peripheral circuit structure PERI.

The cell structure CELL may include a cell substrate 100, a first mold structure MS1, a first channel structure CH1, a second channel structure CH2, a sacrificial insulating layer 250, an upper insulating layer 260, a select gate electrode 270, a bit line 294, etc.

For example, the cell substrate 100 may include a semiconductor substrate such as a silicon substrate, a germanium substrate, or a silicon-germanium substrate. In some example embodiments, the cell substrate 100 may include a silicon-on-insulator (SOI) substrate or a germanium-on-insulator (GOI) substrate, etc. In some example embodiments, the cell substrate 100 may include polysilicon (poly Si).

The cell substrate 100 may include a first side 100_A and a second side 100_B opposite the first side 100_A. The first side 100_A of the cell substrate 100 may be a side on which the first mold structure MS1 and the first channel structure CH1 are disposed. The first side 100_A of the cell substrate 100 may be referred to as a front side of the cell substrate 100. The second side 100_B of the cell substrate 100 may be referred to as a back side of the cell substrate 100.

The first mold structure MS1 may be formed on the first side 100_A of the cell substrate 100. The first mold structure MS1 may include a plurality of mold insulating layers 110 and a plurality of gate electrodes 120 alternately stacked on top of each other in a third direction D3. Each of the mold insulating layers 110 and each of the gate electrodes 120 may have a layered structure extending parallel to the first side 100_A of the cell substrate 100. The gate electrodes 120 may be stacked in order on the cell substrate 100 while being spaced apart from each other by the mold insulating layer 110.

The mold insulating layer 110 may be disposed on an uppermost end of the first mold structure MS1. The mold insulating layer 110 disposed on the uppermost end of the first mold structure MS1 may be in contact with the sacrificial insulating layer 250. The mold insulating layer 110 disposed on the uppermost end of the first mold structure MS1 may have a greater thickness than the other mold insulating layers 110. However, example embodiments are not limited thereto. The thickness of the mold insulating layer 110 may refer to a thickness in the third direction D3.

In some example embodiments, some of the gate electrodes 120 of the plurality of gate electrodes 120 may be used as a ground select line GSL and an erase control line ECL of the semiconductor memory device. For example, the gate electrodes 120 of the plurality of gate electrodes 120, which are adjacent to source structures 102 and 104, may be used as the erase control line ECL. The erase control line ECL may be used as a gate electrode of an erase transistor. The erase transistor may generate a gate induced drain leakage (GIDL) current to perform an erase operation on a plurality of memory cell transistors. The gate electrode 120 adjacent to the erase control line ECL may be provided as a ground select line GSL. However, example embodiments are not limited thereto. The arrangement and number of the ground select lines GSL may vary.

The mold insulating layer 110 may include an insulating material. For example, the mold insulating layer 110 may include at least one of silicon oxide, silicon nitride, or silicon oxynitride, but example embodiments are not limited thereto.

The gate electrode 120 may include a conductive material. For example, the gate electrode 120 may include metal (e.g., tungsten (W), cobalt (Co), or nickel (Ni) or a semiconductor material (e.g., silicon), but example embodiments are not limited thereto.

The first channel structure CH1 may penetrate through the first mold structure MS1. For example, the first channel structure CH1 may penetrate through and intersect each of the plurality of mold insulating layers 110 and the plurality of gate electrodes 120. The first channel structure CH1 may be disposed in a first channel hole extending in the third direction D3. The first channel structure CH1 may have a pillar shape (e.g., a cylindrical shape) extending in the third direction D3. In some example embodiments, the cross section of the first channel structure CH1 may have an inclined side such that its width is progressively narrowed toward the cell substrate 100. However, example embodiments are not limited thereto.

As illustrated in FIGS. 3 and 4, the first channel structure CH1 may include an information storage film 140, a first semiconductor pattern 150, and a channel pad 160.

The first semiconductor pattern 150 may extend in the third direction D3 and penetrate through the first mold structure MS1. The first semiconductor pattern 150 is illustrated to have a cup shape, but example embodiments are not limited thereto. For example, the first semiconductor pattern 150 may have various shapes such as a cylindrical shape, a rectangular cylindrical shape, a filled pillar shape, etc. For example, the first semiconductor pattern 150 may include a semiconductor material such as a single crystal silicon, a polycrystalline silicon, an organic semiconductor material, or a carbon nanostructure, etc., although example embodiments are not limited thereto.

The information storage film 140 may be interposed between the first semiconductor pattern 150 and each of the gate electrodes 120. For example, the information storage film 140 may extend along an outer side surface of the first semiconductor pattern 150. For example, the information storage film 140 may include at least one of silicon oxide, silicon nitride, silicon oxynitride, or a high-k material having a higher dielectric constant than silicon oxide. For example, the high-k material may include at least one of aluminum oxide, hafnium oxide, lanthanum oxide, tantalum oxide, titanium oxide, lanthanum hafnium oxide, lanthanum aluminum oxide, dysprosium scandium oxide, or a combination thereof.

In some example embodiments, the first channel structures CH1 may be arranged in a zigzag fashion. For example, as illustrated in FIG. 1, the first channel structures CH1 may be arranged to cross each other in a first direction D1 and a second direction D2. The first channel structures CH1 arranged in the zigzag fashion may further improve the integration density of the semiconductor memory device. In some example embodiments, the first channel structures CH1 may be arranged in a honeycomb fashion.

In some example embodiments, the information storage film 140 may include multiple films. The information storage film 140 may include a tunnel insulating film 142, a charge storage film 144, and a blocking insulating film 146, which may be stacked in order on the outer side surface of the first semiconductor pattern 150.

For example, the tunnel insulating film 142 may include the silicon oxide or a high-k material (e.g., aluminum oxide (Al₂O₃) or hafnium oxide (HfO₂)) having a higher dielectric constant than the silicon oxide. For example, the charge storage film 144 may include the silicon nitride. For example, the blocking insulating film 146 may include the silicon oxide or a high-k material (e.g., aluminum oxide (Al₂O₃) or hafnium oxide (HfO₂)) having a higher dielectric constant than the silicon oxide.

In some example embodiments, the first channel structure CH1 may further include a filling insulating layer 148. The filling insulating layer 148 may be fill the inside of the first semiconductor pattern 150 having a cup shape. For example, the filling insulating layer 148 may include an insulating material such as silicon oxide, but example embodiments are not limited thereto.

The channel pad 160 may be disposed on an inner upper portion of the first semiconductor pattern 150. The channel pad 160 may be electrically connected to the first semiconductor pattern 150. The first semiconductor pattern 150 and the information storage film 140 may surround the channel pad 160. An upper surface of the channel pad 160 may be co-planar with the upper surface of the first mold structure MS1. The upper surface of the first mold structure MS1 may be an upper surface of the uppermost mold insulating layer 110 of the plurality of mold insulating layers 110. For example, the channel pad 160 may include polysilicon doped with impurities, but example embodiments are not limited thereto.

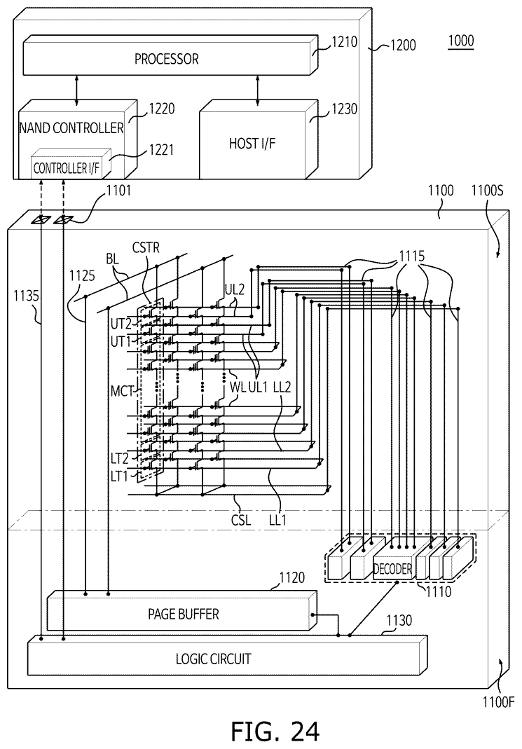

In some example embodiments, the source structures 102 and 104 may be formed on the cell substrate 100. The source structures 102 and 104 may be disposed between the cell substrate 100 and the first mold structure MS1. For example, the source structures 102 and 104 may extend along the upper surface of the cell substrate 100. The source structures 102 and 104 may be formed such that they are connected to the semiconductor pattern 150 and/or the information storage film 140 of the first channel structure CH1. For example, as illustrated in FIG. 3, a portion of the source structures 102 and 104 may penetrate through the information storage film 140 and contact the semiconductor pattern 150. The source structures 102 and 104 may be used as a common source line (e.g., CSL of FIG. 24) of the semiconductor memory device. For example, the source structures 102 and 104 may include polysilicon or metal doped with impurities, but example embodiments are not limited thereto.

In some example embodiments, the first channel structure CH1 may penetrate through the source structures 102 and 104. For example, a lower portion of the first channel structure CH1 may penetrate through the source structures 102 and 104 and be disposed in the cell substrate 100.

In some example embodiments, the source structures 102 and 104 may include multiple films. For example, the source structures 102 and 104 may include a first source layer 104 and a second source layer 102 which may be stacked in order on the cell substrate 100. Each of the first source layer 104 and the second source layer 102 may include polysilicon doped with impurities or polysilicon undoped with impurities, but example embodiments are not limited thereto. The first source layer 104 may be in contact with the semiconductor pattern 150 and provided as a common source line (e.g., CSL of FIG. 24) of the semiconductor memory device. The second source layer 102 may be used as a support layer for mitigating or preventing the mold stack from collapsing or falling in a replacement process for forming the first source layer 104.

The first mold structure MS1 may be divided by word line isolation patterns WC to form a memory cell block. For example, the word line isolation pattern WC may include at least one of an insulating material such as silicon oxide, silicon nitride, or silicon oxynitride, but example embodiments are not limited thereto.

The sacrificial insulating layer 250 may be disposed on the first mold structure MS1, the first channel structure CH1, and the word line isolation pattern WC. The sacrificial insulating layer 250 may extend in the first direction D1 and the second direction D2. The sacrificial insulating layer 250 may surround a portion of the second channel structure CH2. The sacrificial insulating layer 250 may expose at least a portion of an upper surface of the first channel structure CH1. In some example embodiments, the sacrificial insulating layer 250 may be in contact with the upper surface of the first mold structure MS1 and a portion of the upper surface of the first channel structure CH1.

The upper insulating layer 260 may be disposed on the sacrificial insulating layer 250. For example, the upper insulating layer 260 may be disposed along the upper surface of the sacrificial insulating layer 250. The upper insulating layer 260 may extend in the first and second directions D1 and D2. The upper insulating layer 260 may surround a portion of the second channel structure CH2.

Each of the sacrificial insulating layer 250 and the upper insulating layer 260 may include an insulating material. The sacrificial insulating layer 250 may include a different material from the upper insulating layer 260. The sacrificial insulating layer 250 may have etch selectivity with respect to the upper insulating layer 260. For example, the sacrificial insulating layer 250 may include silicon nitride, and the upper insulating layer 260 may include silicon oxide. However, example embodiments are not limited thereto.

The select gate electrode 270 may be disposed on the upper insulating layer 260. For example, the select gate electrode 270 may be disposed along an upper surface of the upper insulating layer 260. The select gate electrode 270 may be disposed to be spaced apart from the first channel structure CH1 in the third direction D3. The upper insulating layer 260 and the sacrificial insulating layer 250 may be disposed between the select gate electrode 270 and the first channel structure CH1.

In some example embodiments, the select gate electrode 270 may include a different material from the gate electrode 120. For example, the select gate electrode 270 may include a semiconductor material such as polycrystalline silicon. In this case, a thickness of the select gate electrode 270 in the third direction D3 may be greater than a thickness of the gate electrode 120 in the third direction D3. However, example embodiments are not limited thereto. For example, the select gate electrode 270 may include the same material as the gate electrode 120. For example, the select gate electrode 270 may include at least one of metal (e.g., TiN or TaN) or transition metal (e.g., Ti or Ta).

A first interlayer insulating layer 282 may be disposed on the select gate electrode 270. The first interlayer insulating layer 282 may surround an upper portion of the second channel structure CH2. In some example embodiments, an upper surface of the first interlayer insulating layer 282 may be co-planar with an upper surface of the second channel structure CH2. For example, the first interlayer insulating layer 282 may include one of silicon oxide, silicon nitride, or silicon oxynitride.

The second channel structure CH2 may penetrate through the first interlayer insulating layer 282, the select gate electrode 270, the upper insulating layer 260, and the sacrificial insulating layer 250 and connected to the first channel structure CH1. The second channel structure CH2 may be located on the first channel structure CH1. The second channel structure CH2 may extend in the third direction D3 and be connected to the first channel structure CH1. The second channel structure CH2 may be a string select channel structure of string select transistors UT1 and UT2 of FIG. 24.

The second channel structures CH2 may be located on the first mold structure MS1 in rows and columns and spaced apart from each other. For example, the second channel structures CH2 may be disposed in a grid pattern on a plane at which the first direction D1 and the second direction D2 intersect each other, or may be disposed in a zigzag fashion in one direction.

An upper isolation pattern 275 may penetrate through the select gate electrode 270 and an upper surface (or an upper portion) the upper insulating layer 260. The upper isolation pattern 275 may extend in the second direction D2. The upper surface of the upper isolation pattern 275 may be positioned at substantially the same level as the upper surface of the select gate electrode 270. The lower surface of the upper isolation pattern 275 may be positioned at a higher level than the upper surface of the first mold structure MS1.

The upper isolation pattern 275 may include an insulating material. For example, the upper isolation pattern 275 may include an insulating material such as silicon oxide or silicon nitride. However, example embodiments are not limited thereto.

The upper isolation pattern 275 may include a first sub-pattern 275_1 and a second sub-pattern 275_2. The first sub-pattern 275_1 may overlap the word line isolation pattern WC in the third direction D3. The second sub-pattern 275_2 may overlap the first mold structure MS1 in the third direction D3. FIG. 1 illustrates that two second sub-patterns 275_2 are disposed between two adjacent first sub-patterns 275_1, but example embodiments are not limited thereto. The number of second sub-patterns 275_2 may be three or more.

As illustrated in FIG. 1, when viewed in a plan view, one second channel structure CH2 may overlap one first channel structure CH1 in the third direction D3. That is, a second channel structure CH2 may be disposed to correspond to a first channel structure CH1. Some of the plurality of second channel structures CH2 may be disposed to be spaced apart from the corresponding first channel structure CH1 in the first direction D1. Specifically, the center of some of the second channel structures CH2 may be spaced apart from the center of corresponding ones of the first channel structures CH1 in the first direction D1, respectively. That is, at least a portion of a second channel structure CH2 may overlap a corresponding one of the first channel structures CH1 in the third direction D3.

When viewed in a plan view, in some example embodiments, a distance between a corresponding pair of a second channel structure CH2 and a first channel structure CH1 that are spaced apart from each other in the first direction D1 may not be constant. For example, the spacing between a second channel structure CH2 and a corresponding first channel structure CH1 that are spaced apart from each other (e.g., a distance between a center of a second channel structure CH2 and a corresponding first channel structure CH1) in the first direction D1 may increase, as being closer to the second sub-pattern 275_2.

A diameter of the second channel structure CH2 may be less than a diameter of the first channel structure CH1. In some example embodiments, on a cross section formed by the first direction D1 and the second direction D2, the diameter of the second channel structure CH2 may be the same as a width of the second channel structure CH2 in the first direction D1, and the diameter of the first channel structure CH1 may be the same as the width of the first channel structure CH1 in the first direction D1. The width of the second channel structure CH2 in the first direction D1 may be less than the width of the first channel structure CH1 in the first direction D1. However, example embodiments are not limited thereto. For example, the diameter of the second channel structure CH2 may be equal to or greater than the diameter of the first channel structure CH1.

Hereinafter, the second channel structure CH2 will be described in detail with reference to FIGS. 2 and 4.

The second channel structure CH2 may include a dielectric pattern 210, a liner film 220, a second semiconductor pattern 230, and a filling pattern 240.

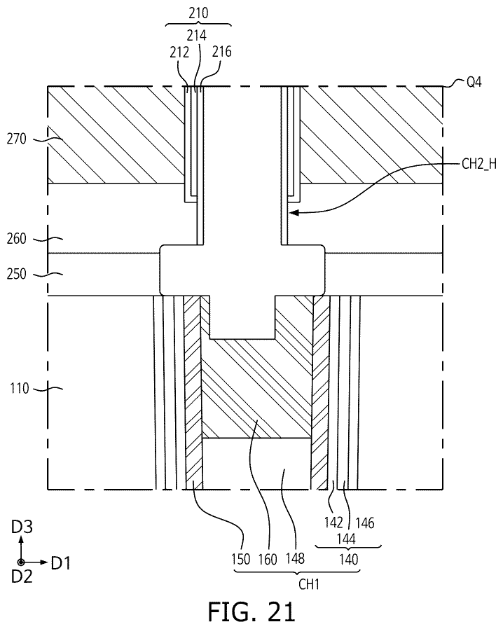

The second channel structure CH2 may be disposed in a second channel hole CH2_H. The shape, etc. of the second channel structure CH2 will be described below with reference to FIG. 21. A side surface of the second channel hole CH2_H may be defined by the first interlayer insulating layer 282, the select gate electrode 270, the upper insulating layer 260, and the sacrificial insulating layer 250. A bottom surface of the second channel hole CH2_H may be defined by the channel pad 160. The bottom surface of the second channel hole CH2_H may be disposed in the channel pad 160. The bottom surface of the second channel hole CH2_H may be disposed at a lower level than an upper surface of the channel pad 160. The second channel hole CH2_H may extend in the third direction D3.

In some example embodiments, the second channel hole CH2_H may include a step. The step of the second channel hole CH2_H may be disposed on the upper insulating layer 260. The dielectric pattern 210 may be disposed on the step of the second channel hole CH2_H. For example, a first dielectric layer 212 and a second dielectric layer 214 may be disposed above the step of the second channel hole CH2_H. The first dielectric layer 212 may extend along a sidewall disposed above the step of the side of the second channel hole CH2_H. The first dielectric layer 212 may be in contact with the upper insulating layer 260, the select gate electrode 270, and the first interlayer insulating layer 282.

The second dielectric layer 214 may be disposed on the first dielectric layer 212. The second dielectric layer 214 may extend along the first dielectric layer 212. The second dielectric layer 214 may be disposed above the step of the second channel hole CH2_H.

A third dielectric layer 216 may be disposed on the second dielectric layer 214. The third dielectric layer 216 may extend along the second dielectric layer 214 and be disposed on the upper insulating layer 260. That is, the third dielectric layer 216 may be disposed above and below the step of the second channel hole CH2_H. The third dielectric layer 216 may extend in the third direction D3. One end of the third dielectric layer 216 may be disposed on the liner film 220.

For example, the first dielectric layer 212 may include the silicon oxide or a high-k material (e.g., aluminum oxide (Al₂O₃) or hafnium oxide (HfO₂)) having a higher dielectric constant than the silicon oxide. For example, the second dielectric layer 214 may include silicon nitride. For example, the third dielectric layer 216 may include the silicon oxide or a high-k material (e.g., aluminum oxide (Al₂O₃) or hafnium oxide (HfO₂)) having a higher dielectric constant than the silicon oxide.

The liner film 220 may be disposed on the side surface and bottom surface of the third dielectric layer 216 and the second channel hole CH2_H. For example, a portion of the liner film 220 may extend along the third dielectric layer 216. The liner film 220 may be disposed along portions of the side of the second channel hole CH2_H where the dielectric pattern 210 is not disposed, and the bottom (e.g., the bottom surface) of the second channel hole CH2_H. In some example embodiments, the liner film 220 may be conformally disposed. The liner film 220 may be disposed along the outer side surface of the second semiconductor pattern 230. The liner film 220 may surround the second semiconductor pattern 230. The liner film 220 may be in contact with the first channel structure CH1. For example, the liner film 220 may be in contact with the channel pad 160 of the first channel structure CH1 and the first semiconductor pattern 150.

The liner film 220 may be a carbon rich and nitrogen rich silicon layer. For example, the liner film 220 may include silicon carbon nitride (SiCN). In some example embodiments, the liner film 220 may be formed using an organosilane precursor.

The second semiconductor pattern 230 may be disposed on the liner film 220. For example, the second semiconductor pattern 230 may be disposed along the liner film 220. The second semiconductor pattern 230 may be electrically connected to the first channel structure CH1 through the liner film 220. Due to the presence of the liner film 220, the second semiconductor pattern 230 may not be in contact with the first channel structure CH1. When viewed in a cross section in the first direction D1 and the third direction D3, the liner film 220 and the second semiconductor pattern 230 may form a cross shape.

Fluorine (F₂) gas may leak out of the gate electrode 120 during a process of forming the gate electrode 120, etc. If the fluorine gas contacts the second semiconductor pattern 230, the second semiconductor pattern 230 may be oxidized by the fluorine gas. In the semiconductor memory device according to some example embodiments, the liner film 220 may surround the outer side surface of the second semiconductor pattern 230. The liner film 220 may block the ingress of fluorine gas into the second semiconductor pattern 230, thereby reducing or preventing the second semiconductor pattern 230 from being oxidized. Accordingly, reliability of the semiconductor memory device can be improved.

A portion of the outer side surface of the second semiconductor pattern 230 may be in contact with the dielectric pattern 210. An inner side surface of the second semiconductor pattern 230 may be in contact with the filling pattern 240. The second semiconductor pattern 230 may be disposed between the dielectric pattern 210 and the filling pattern 240. The filling pattern 240 may be disposed inside the semiconductor pattern 230 (e.g., in a space defined by the semiconductor pattern 230). The second semiconductor pattern 230 may be integrally formed. For example, the second semiconductor pattern 230 may be formed of the same crystalline material (e.g., the same crystal direction).

The second semiconductor pattern 230 may include a vertical portion 230_VP, a horizontal portion 230_HP, and a lower portion 230_BP.

The vertical portion 230_VP of the second semiconductor pattern 230 may extend in the third direction D3. One end of the vertical portion 230_VP of the second semiconductor pattern 230 may penetrate through at least a portion of the upper surface of the channel pad 160. One end of the vertical portion 230_VP of the second semiconductor pattern 230 may be disposed in the channel pad 160. One end of the vertical portion 230_VP of the second semiconductor pattern 230 may be connected to the lower portion 230_BP of the second semiconductor pattern 230.

The lower portion 230_BP of the second semiconductor pattern 230 may be disposed on the channel pad 160. The lower portion 230_BP of the second semiconductor pattern 230 may be disposed at a lower level than the upper surface of the channel pad 160. The lower portion 230_BP of the second semiconductor pattern 230 may be disposed in the channel pad 160. The liner film 220 may be disposed between the lower portion 230_BP of the second semiconductor pattern 230 and the channel pad 160. The lower portion 230_BP of the second semiconductor pattern 230 may be disposed at a lower level than the horizontal portion 230_HP of the second semiconductor pattern 230.

The vertical portion 230_VP and the lower portion 230_BP of the second semiconductor pattern 230 may have a cup shape. However, example embodiments are not limited thereto. For example, the vertical portion 230_VP and the lower portion 230_BP of the second semiconductor pattern 230 may have various shapes such as a cylindrical shape, a square cylindrical shape, a filled pillar shape, etc.

The horizontal portion 230_HP of the second semiconductor pattern 230 may protrude from the vertical portion 230_VP of the second semiconductor pattern 230 in the first and second directions D1 and D2. The horizontal portion 230_HP of the second semiconductor pattern 230 may be disposed on the first mold structure MS1. The horizontal portion 230_HP of the second semiconductor pattern 230 may be disposed on the upper surface of the channel pad 160. When viewed in a plan view, the horizontal portion 230_HP of the second semiconductor pattern 230 may have a ring or donut shape. A diameter of the horizontal portion 230_HP of the second semiconductor pattern 230 may be greater than a diameter of the vertical portion 230_VP of the second semiconductor pattern 230.

The sacrificial insulating layer 250 may expose a portion of the upper surface of the first channel structure CH1. The horizontal portion 230_HP of the second semiconductor pattern 230 may be disposed on the upper surface of the first channel structure CH1 exposed by the sacrificial insulating layer 250. The sacrificial insulating layer 250 may overlap the horizontal portion 230_HP of the second semiconductor pattern 230 in the first direction D1. In other words, a height from the upper surface of the first mold structure MS1 to the sacrificial insulating layer 250 may be equal to or less than a height from the upper surface of the first mold structure MS1 to the horizontal portion 230_HP of the second semiconductor pattern 230. In some example embodiments, the horizontal portion 230_HP of the second semiconductor pattern 230 may overlap a portion of the upper insulating layer 260 in the third direction D3.

Meanwhile, referring to FIGS. 4 and 5, a specific element E1 may be disposed on an inner side surface of the dielectric pattern 210. For example, an inner side surface of the third dielectric layer 216 of the dielectric pattern 210 may include the specific element E1. The inner side surface of the third dielectric layer 216 may be in contact with an outer side surface of the liner film 220. An inner side surface of the third dielectric layer 216 and the outer side surface of the liner film 220 may be a boundary surface between the third dielectric layer 216 and the liner film 220.

Although not illustrated, the specific element E1 may be included in a configuration in contact with the outer side surface of the liner film 220. For example, a boundary surface where the liner film 220 and the sacrificial insulating layer 250 contact each other, a boundary surface where the liner film 220 and the upper insulating layer 260 contact each other, and a boundary surface where the liner film 220 and the first channel structure CH1 contact each other may include the specific element E1.

The specific element E1 may include a halogen element. For example, the specific element E1 may include at least one of bromine (Br), fluorine (F), chlorium (Cl), or iodine (I).

Referring back to FIGS. 1 to 5, a second interlayer insulating layer 284 may be disposed on the first interlayer insulating layer 282. A third interlayer insulating layer 286 may be disposed on the second interlayer insulating layer 284. The second interlayer insulating layer 284 and the third interlayer insulating layer 286 may be stacked in order on the first interlayer insulating layer 282.

Each of the second interlayer insulating layer 284 and the third interlayer insulating layer 286 may include an insulating material. For example, each of the second interlayer insulating layer 284 and the third interlayer insulating layer 286 may include one of silicon oxide, silicon nitride, or silicon oxynitride. In some example embodiments, a boundary between the first interlayer insulating layer 282 and the second interlayer insulating layer 284 and/or a boundary between the second interlayer insulating layer 284 and the third interlayer insulating layer 286 may not be distinguished from each other.

An upper via 285 may be disposed on the second channel structure CH2. The upper via 285 may be in contact with the upper surface of the second channel structure CH2. For example, the upper via 285 may penetrate through the second interlayer insulating layer 284 and contact the upper pad 245 of the second channel structure CH2. The upper via 285 may include a conductive material.

A bit line plug 292 may be disposed on the upper via 285. The bit line plug 292 may penetrate through the third interlayer insulating layer 286 and contact the upper via 285. One end of the bit line plug 292 may be connected to the upper via 285, and the other end of the bit line plug 292 may be connected to the bit line 294. The bit line plug 292 may include a conductive material.

The bit line 294 may be disposed on the bit line plug 292 and the third interlayer insulating layer 286. The bit line 294 may be connected to some of a plurality of bit line plugs 292. The bit line 294 may extend in the first direction D1. The bit line 294 may intersect the upper isolation pattern 275. The bit line 294 may be connected to the second channel structure CH2 through the bit line plug 292. The bit line 294 may correspond to BL of FIG. 24.

The peripheral circuit region PERI may include a peripheral circuit substrate 300, a peripheral circuit element 360, and a peripheral circuit wiring structure 380.

The peripheral circuit substrate 300 may be disposed under the cell substrate 100. For example, an upper surface of the peripheral circuit substrate 300 may face the second side 100_B of the cell substrate 100. For example, the peripheral circuit substrate 300 may include a semiconductor substrate such as a silicon substrate, a germanium substrate, or a silicon-germanium substrate. In some example embodiments, the peripheral circuit substrate 300 may include a silicon-on-insulator (SOI) substrate, a germanium-on-insulator (GOI) substrate, etc.

The peripheral circuit element 360 may be formed on the peripheral circuit substrate 300. The peripheral circuit element 360 may configure a peripheral circuit that controls the operation of the semiconductor memory device. For example, the peripheral circuit element 360 may include a logic circuit 1130, a page buffer 1120, a decoder 1110, etc. of FIG. 24. In the following description, the surface of the peripheral circuit substrate 300 on which the peripheral circuit element 360 is disposed may be referred to as a front side of the peripheral circuit substrate 300. Conversely, the surface of the peripheral circuit substrate 300 opposite to the front side of the peripheral circuit substrate 300 may be referred to as a back side of the peripheral circuit substrate 300.

For example, the peripheral circuit element 360 may include a transistor, but example embodiments are not limited thereto. For example, the peripheral circuit element 360 may include not only various active elements such as transistors, etc., but also various passive elements such as capacitors, registers, inductors, etc.

The peripheral circuit wiring structure 380 may be formed on the peripheral circuit element 360. For example, a peripheral wiring insulating film 340 may be formed on the front side of the peripheral circuit substrate 300, and the peripheral circuit wiring structure 380 may be formed in the peripheral wiring insulating film 340. The peripheral circuit wiring structure 380 may be electrically connected to the peripheral circuit element 360. The number, arrangement, etc. of the layers of the peripheral circuit wiring structure 380 illustrated herein are merely examples, and example embodiments are not limited thereto.

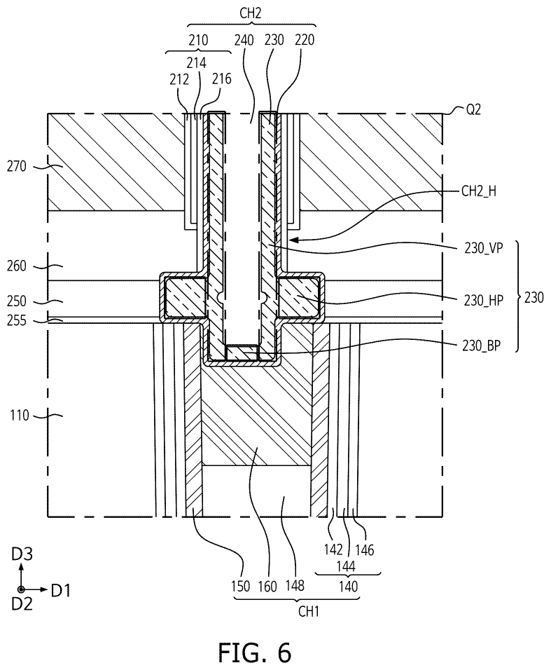

FIG. 6 is a diagram provided to explain a semiconductor memory device according to an example embodiment. For reference, FIG. 6 may correspond to an enlarged view of the region Q2 of FIG. 2. For convenience of description, different configurations from those described in FIGS. 1 to 5 will be mainly described.

Referring to FIG. 6, the semiconductor memory device according to an example embodiment may further include an etching stop layer 255.

The etching stop layer 255 may be disposed on the upper surface of the first mold structure MS1. The etching stop layer 255 may be disposed between the first mold structure MS1 and the sacrificial insulating layer 250. The etching stop layer 255 may expose a portion of the first channel structure CH1. The horizontal portion 230_HP of the second semiconductor pattern 230 may be disposed on the first channel structure CH1 exposed by the etching stop layer 255.

The etching stop layer 255 may include an insulating material. For example, the etching stop layer 255 may include silicon oxide. However, example embodiments are not limited thereto.

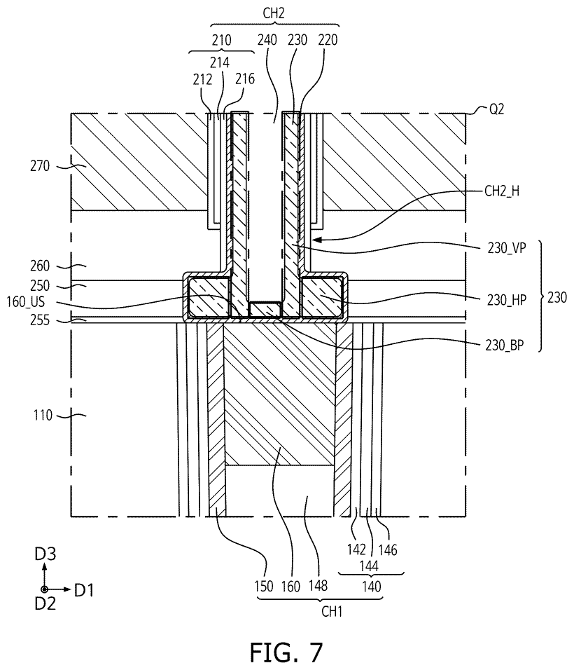

FIG. 7 is a diagram provided to explain a semiconductor memory device according to an example embodiment. For reference, FIG. 7 may correspond to an enlarged view of the region Q2 of FIG. 2. For convenience of description, different configurations from those described in FIGS. 1 to 6 will be mainly described.

Referring to FIG. 7, in the semiconductor memory device according to an example embodiment, the second channel structure CH2 may be disposed on the upper surface of the first channel structure CH1. The second channel structure CH2 may not penetrate through an upper surface 160_US of the channel pad 160. In other words, the liner film 220 may extend along the upper surface 160_US of the channel pad 160.

The second semiconductor pattern 230 may be disposed on the liner film 220. In a cross section formed by the first direction D1 and the third direction D3, the second semiconductor pattern 230 may be similar to the shape of a “T” rotated by 180 degrees.

The second semiconductor pattern 230 may include a vertical portion 230_VP, a horizontal portion 230_HP, and a lower portion 230_BP. One end of the vertical portion 230_VP of the second semiconductor pattern 230 may not penetrate through the upper surface 160_US of the channel pad 160. The vertical portion 230_VP and the lower portion 230_BP of the second semiconductor pattern 230 may be disposed at a higher level than the upper surface 160_US of the channel pad 160.

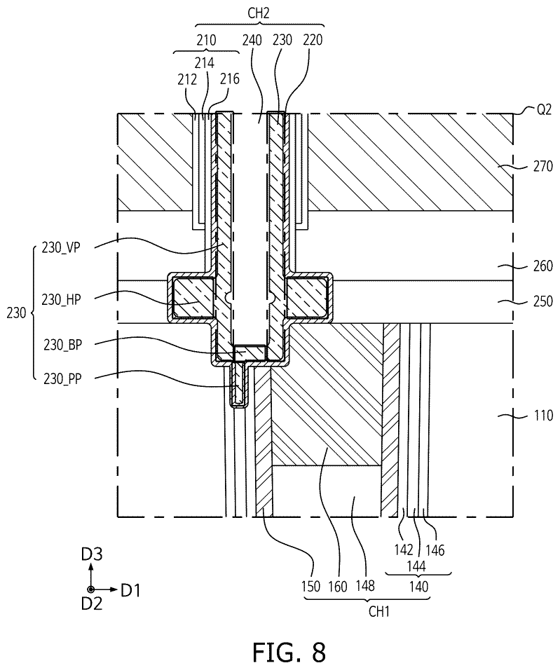

FIG. 8 is a diagram provided to explain a semiconductor memory device according to an example embodiment. For reference, FIG. 8 may correspond to an enlarged view of the region Q2 of FIG. 2. For convenience of description, different configurations from those described in FIGS. 1 to 5 will be mainly described.

Referring to FIG. 8, in the semiconductor memory device according to an example embodiment, one end of the vertical portion 230_VP of the second semiconductor pattern 230 may penetrate through at least a portion of the upper surface of the channel pad 160 and at least a portion of the information storage film 140. The second semiconductor pattern 230 may further include a protrusion 230_PP.

The protrusion 230_PP of the second semiconductor pattern 230 may protrude from the lower portion 230_BP of the second semiconductor pattern 230 toward the cell substrate 100. The protrusion 230_PP of the second semiconductor pattern 230 may be disposed on the charge storage film 144. The protrusion 230_PP of the second semiconductor pattern 230 may overlap the charge storage film 144 in the third direction D3. The protrusion 230_PP of the second semiconductor pattern 230 may be formed by removing an upper portion of the charge storage film 144.

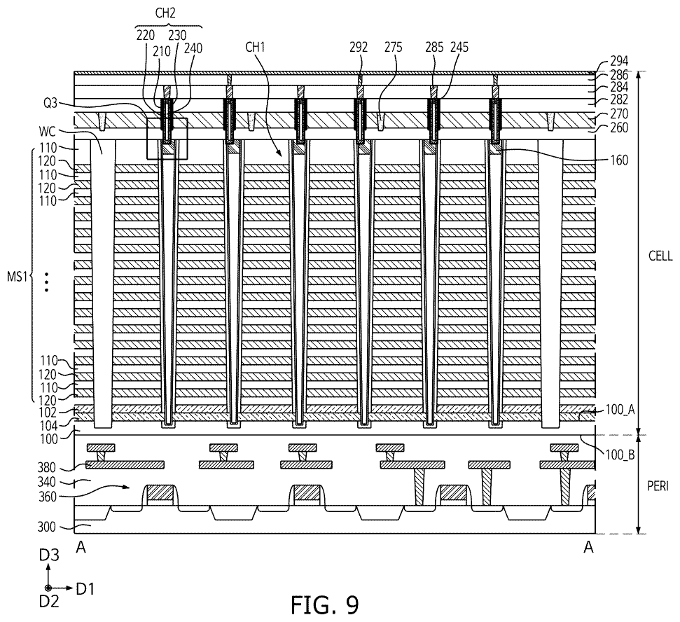

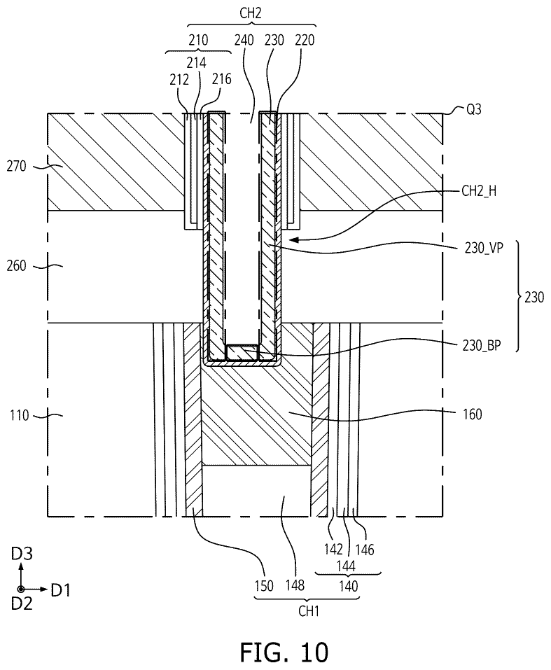

FIG. 9 is a diagram provided to explain a semiconductor memory device according to an example embodiment. FIG. 10 is an enlarged view provided to explain the region Q3 of FIG. 9. For convenience of description, different configurations from those described in FIGS. 1 to 5 will be mainly described.

Referring to FIGS. 9 and 10, in the semiconductor memory device according to an example embodiment, the upper insulating layer 260 may be disposed on the first mold structure MS1. The upper insulating layer 260 may be in contact with the upper surface of the first mold structure MS1. The select gate electrode 270 may be disposed on the upper surface of the upper insulating layer 260.

The second channel structure CH2 may penetrate through the select gate electrode 270, the upper insulating layer 260, and the upper surface (e.g., an upper portion) of the channel pad 160. The liner film 220 may extend in the third direction D3. The liner film 220 may extend linearly on the dielectric pattern 210 and the upper insulating layer 260. The second semiconductor pattern 230 may include the vertical portion 230_VP and the lower portion 230_BP. The second semiconductor pattern 230 may not include the horizontal portion 230_HP of FIG. 4.

Although it is illustrated that the second channel structure CH2 penetrates through the upper surface of the channel pad 160, example embodiments are not limited thereto. For example, the second channel structure CH2 may be in contact with an upper surface of the channel pad 160. The liner film 220 may be disposed on the upper surface of the channel pad 160.

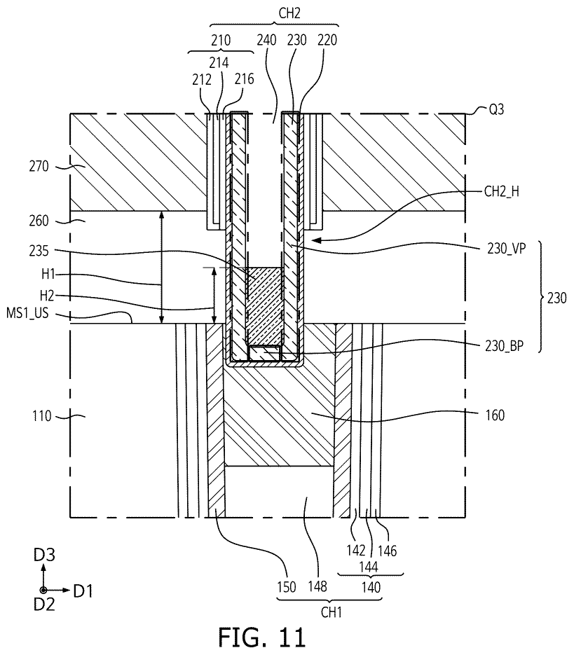

FIG. 11 is a diagram provided to explain a semiconductor memory device according to an example embodiment. For reference, FIG. 11 may correspond to an enlarged view of the region Q3 of FIG. 9. For convenience of description, different configurations from those described in FIGS. 9 and 10 will be mainly described.

Referring to FIG. 11, the semiconductor memory device according to an example embodiment may further include a doping pattern 235.

The doping pattern 235 may be disposed in the second channel structure CH2. The doping pattern 235 may be disposed in the second semiconductor pattern 230 (e.g., in a space defined by the second semiconductor pattern 230). The doping pattern 235 may be in contact with the vertical portion 230_VP and a lower part 230_BP of the second semiconductor pattern 230. The doping pattern 235 may be surrounded by the second semiconductor pattern 230. In some example embodiments, a lower portion of the doping pattern 235 may be disposed at a lower level than the upper surface of the channel pad 160. The doping pattern 235 may include a conductive material. For example, the doping pattern 235 may include doped silicon.

A distance from an upper surface MS1_US of the first mold structure MS1 to the upper surface of the upper insulating layer 260 may be a first distance H1. A distance from the upper surface MS1_US of the first mold structure MS1 to the upper surface of the doping pattern 235 may be a second distance H2. The second distance H2 may be equal to or less than the first distance H1.

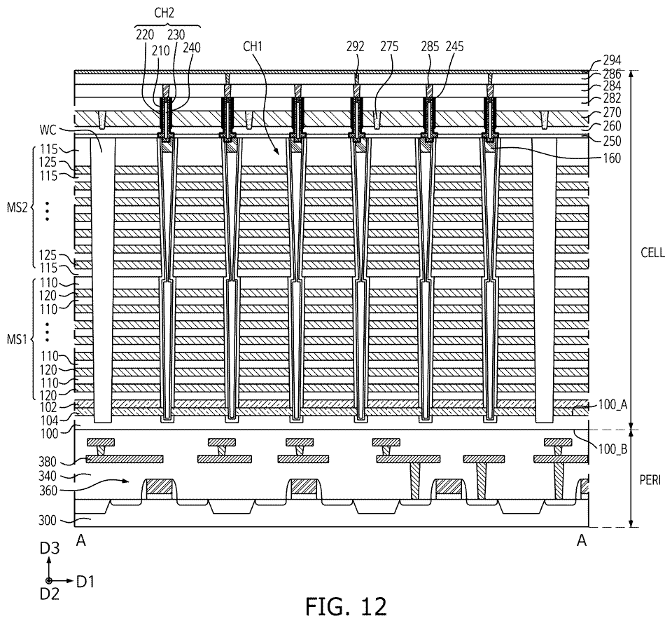

FIG. 12 is a diagram provided to explain a semiconductor memory device according to an example embodiment. For convenience of description, different configurations from those described in FIGS. 1 to 5 will be mainly described.

Referring to FIG. 12, in the semiconductor memory device according to an example embodiment, a second mold structure MS2 and the first mold structure MS1 may be stacked in order on the cell substrate 100.

The second mold structure MS2 may be disposed on the first mold structure MS1. The second mold structure MS2 may include a plurality of second mold insulating layers 115 and a plurality of second gate electrodes 125 alternately stacked on top of each other in the third direction D3. Each of the second mold insulating layer 115 and each of the second gate electrodes 125 may have a layered structure extending parallel to the first side 100_A of the cell substrate 100.

The first channel structure CH1 may extend in the third direction D3 and penetrate through the first mold structure MS1 and the second mold structure MS2. The first channel structure CH1 may have a bent portion between the first mold structure MS1 and the second mold structure MS2.

Although FIG. 12 illustrates that the number of mold structures is two (e.g., MS1 and MS2), example embodiments are not limited thereto. For example, the number of mold structures may be three or four or more.

The sacrificial insulating layer 250 may be disposed on the second mold structure MS2. The sacrificial insulating layer 250, the upper insulating layer 260, and the select gate electrode 270 may be stacked in order on the second mold structure MS2. The second channel structure CH2 may be disposed on the second mold structure MS2. The second channel structure CH2 may be connected to the first channel structure CH1.

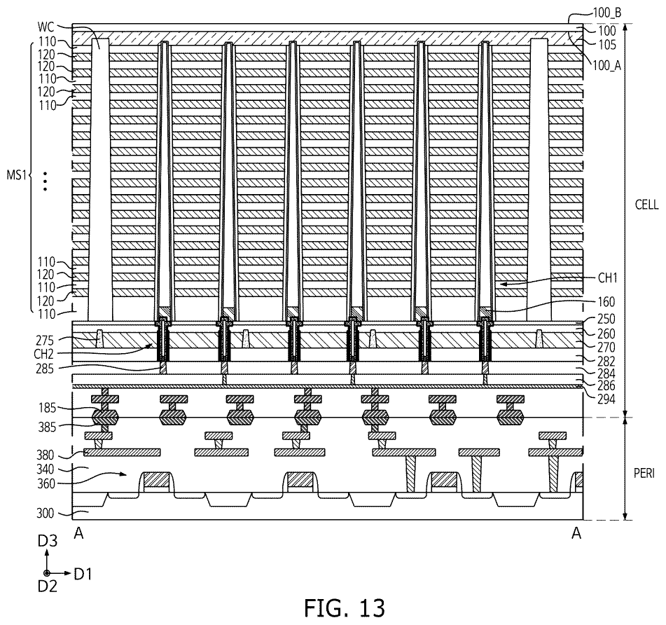

FIG. 13 is a diagram provided to explain a semiconductor memory device according to an example embodiment. For convenience of description, different configurations from those described in FIGS. 1 to 5 will be mainly described.

Referring to FIG. 13, the semiconductor memory device according to an example embodiment may include a common source plate 105.

The common source plate 105 may be disposed on the first side 100_A of the cell substrate 100. The common source plate 105 may be connected to the first channel structure CH1. For example, the common source plate 105 may be electrically connected to the semiconductor pattern of the first channel structure CH1. The common source plate 105 may be used as a common source line (e.g., CSL of FIG. 24) of the semiconductor memory device. For example, the common source plate 105 may include polycrystalline silicon or metal doped with impurities, but example embodiments are not limited thereto.

The first mold structure MS1 may be disposed on the common source plate 105. The first mold structure MS1 may include a plurality of mold insulating layers 110 and a plurality of gate electrodes 120 alternately stacked on top of each other in the third direction D3. The gate electrodes 120 may be stacked in order on the common source plate 105 and spaced apart from each other by the mold insulating layer 110.

In some example embodiments, the cell structure CELL may be stacked on the peripheral circuit structure PERI. The bit line 294 of the cell structure CELL may be stacked on the peripheral wiring insulating film 340.

The semiconductor memory device according to some example embodiments may have a chip-to-chip (C2C) structure. The C2C structure refers to manufacturing an upper chip including the cell structure (CELL) on a first wafer (e.g., the cell substrate 100), manufacturing a lower chip including the peripheral circuit structure (PERI) on the second wafer (e.g., the peripheral circuit substrate 300) that is different from the first wafer, and connecting the upper and lower chips to each other by a bonding method.

In some example embodiments, by the bonding method, it may mean a method of electrically connecting a first bonding metal 185 formed on the lowermost metal layer of the upper chip and a second bonding metal 385 formed on the uppermost metal layer of the lower chip to each other. For example, if the first bonding metal 185 and the second bonding metal 385 are formed of copper (Cu), the bonding method may be a Cu—Cu bonding method. However, this is only an example, and it goes without saying that the first bonding metal 185 and the second bonding metal 385 may be formed of various other metals such as aluminum (Al) or tungsten (W).

The first bonding metal 185 may be electrically connected to the bit line 294. The second bonding metal 385 may be electrically connected to the peripheral circuit wiring structure 380. As the first bonding metal 185 and the second bonding metal 385 are bonded, the bit line 294 may be connected to the peripheral circuit wiring structure 380. Accordingly, the bit line 294 and/or each of the gate electrodes 120 may be electrically connected to the peripheral circuit element 360.

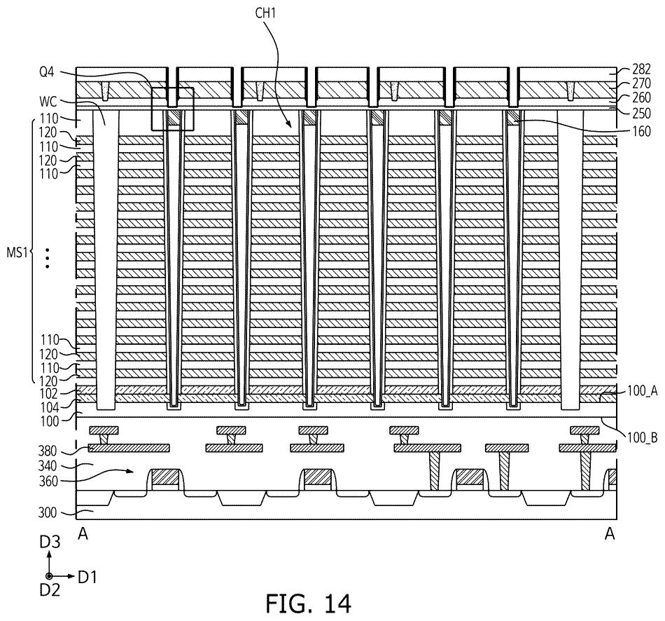

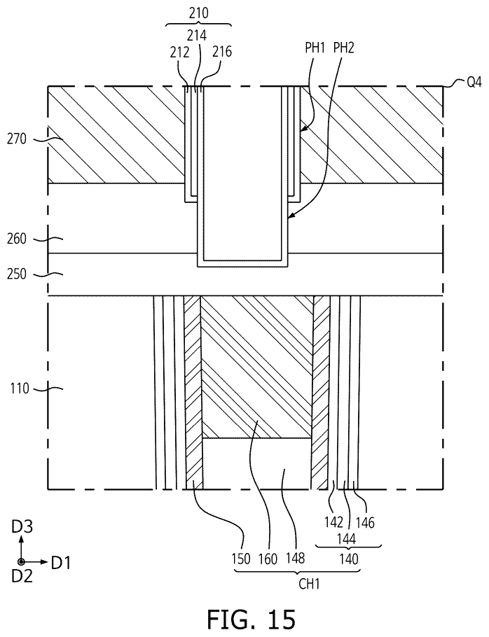

FIGS. 14 to 22 are diagrams showing intermediate stages, provided to explain a method for manufacturing a semiconductor memory device according to an example embodiment. FIG. 14 may correspond to a cross-sectional view taken along line A-A of FIG. 1. FIGS. 15 to 22 are enlarged views provided to explain the region Q4 of FIG. 14.

Referring to FIGS. 14 and 15, the first mold structure MS1 and the first channel structure CH1 may be formed on the cell substrate 100, and the sacrificial insulating layer 250, the upper insulating layer 260, the select gate electrode 270, and the first interlayer insulating layer 282 may be stacked on the first mold structure MS1. The dielectric pattern 210 may be formed.

For example, a first through hole PH1 penetrating through the first interlayer insulating layer 282, the select gate electrode 270, and the upper surface (e.g., an upper portion) of the upper insulating layer 260 may be formed. The bottom portion of the first through hole PH1 may expose the upper insulating layer 260. The first dielectric layer 212 and the second dielectric layer 214 may be stacked in order along the side and the bottom (e.g., the bottom surface) of the first through hole PH1.

A second through hole PH2 extending in the third direction D3 may be formed. For example, the first dielectric layer 212 and the second dielectric layer 214 disposed on the bottom portion of the first through hole PH1 may be removed to form the second through hole PH2. The second through hole PH2 may penetrate through the first interlayer insulating layer 282, the select gate electrode 270, the upper insulating layer 260, and the upper surface (e.g., an upper portion) of the sacrificial insulating layer 250. The bottom portion of the second through hole PH2 may expose the sacrificial insulating layer 250.

The third dielectric layer 216 may be formed along a side (or a sidewall) and a bottom (or a bottom surface) of the second through hole PH2, thereby forming the dielectric pattern 210.

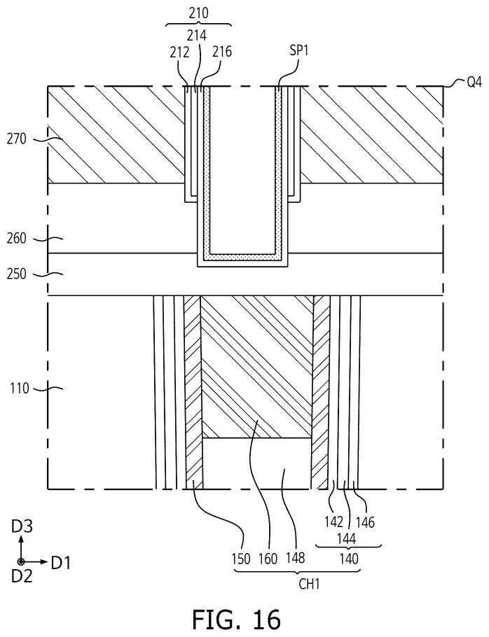

Referring to FIG. 16, a spacer SP1 may be formed on the dielectric pattern 210. The spacer SP1 may be disposed along the third dielectric layer 216. The spacer SP1 may cover the third dielectric layer 216.

The spacer SP1 may include silicon. For example, the spacer SP1 may include amorphous silicon.

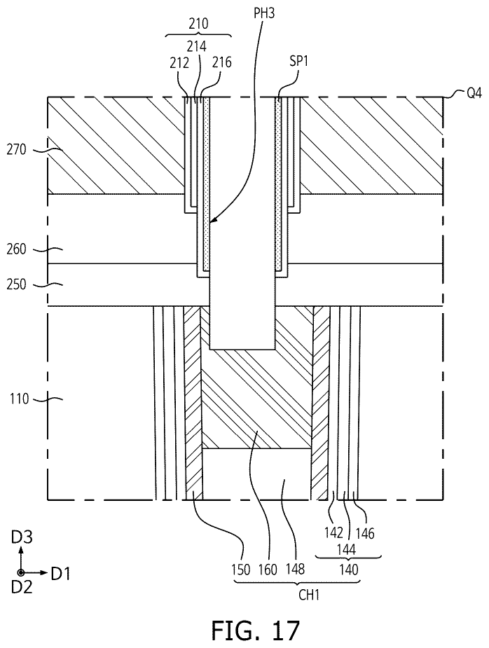

Referring to FIG. 17, a bottom portion of the spacer SP1, a bottom portion of the third dielectric layer 216, a portion of the sacrificial insulating layer 250, and a portion of the channel pad 160 may be removed to form a third through hole PH3.

The third through hole PH3 may extend in the third direction D3. The third through hole PH3 may penetrate through the upper surface of the channel pad 160. The third through hole PH3 may expose the spacer SP1, a side of the sacrificial insulating layer 250, and the channel pad 160.

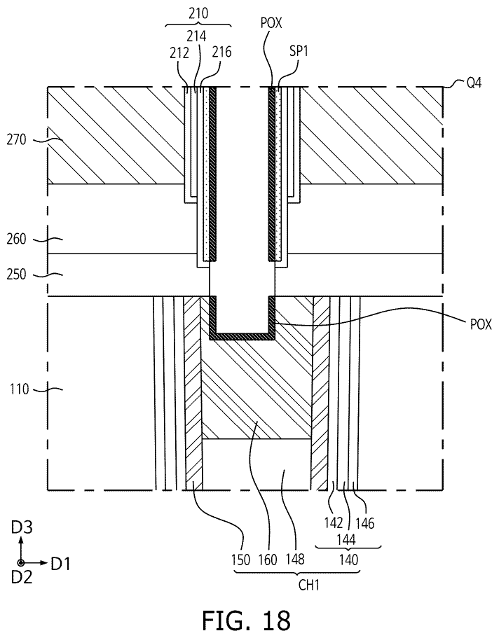

Referring to FIGS. 17 and 18, a pre-insulating layer POX may be disposed on the spacer SP1 and the channel pad 160 exposed by the third through hole PH3. The pre-insulating layer POX may be formed along the spacer SP1 and the channel pad 160. The spacer SP1 and the channel pad 160 may not be exposed by the pre-insulating layer POX. The pre-insulating layer POX may not be disposed on the side of the sacrificial insulating layer 250 exposed by the third through hole PH3.

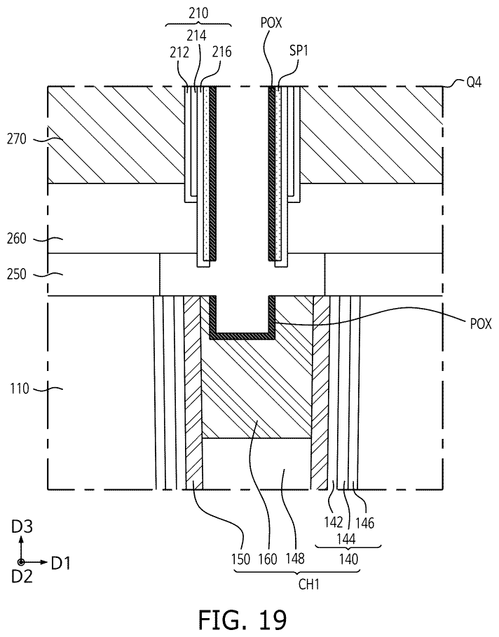

Referring to FIG. 19, a portion of the sacrificial insulating layer 250 may be removed.

For example, a portion of the sacrificial insulating layer 250 exposed by the third through hole PH3 may be removed by a first etching process. The first etching process may use an etchant having an etch selectivity with respect to the pre-insulating layer POX and the sacrificial insulating layer 250. The sacrificial insulating layer 250 may be removed in the first and second directions D1 and D2 by the first etching process.

Thus, the exposed area of the first channel structure CH1 may increase. For example, a portion of the sacrificial insulating layer 250 may be removed to expose portions of the channel pad 160, the first semiconductor pattern 150, and the information storage film 140.

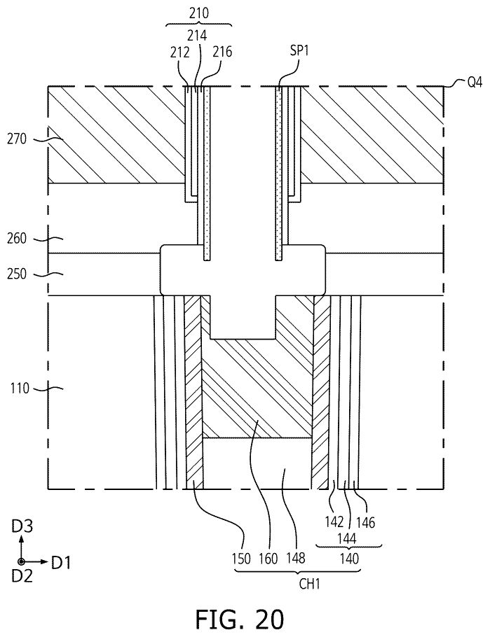

Referring to FIGS. 19 and 20, the pre-insulating layer POX may be removed. A portion of the upper insulating layer 260 and a portion of the third dielectric layer 216 may also be removed upon removal of the pre-insulating layer POX. The removal of the pre-insulating layer POX may result in exposure of the spacer SP1 and the channel pad 160.

Referring to FIG. 21, the spacer SP1 may be removed by a second etching process. The second etching process may be a selective etching process. For example, the second etching process may use an etchant having etch selectivity with respect to the spacer SP1 and the channel pad 160. As described above, the spacer SP1 may include amorphous silicon. The channel pad 160 may include crystalline silicon. The second etching process may selectively remove amorphous silicon and may not remove crystalline silicon.

If the channel pad 160 is removed together upon removal of the spacer SP1, electrical characteristics of the semiconductor memory device may be deteriorated. For example, if a certain portion of the channel pad 160 is removed, the connection between the first channel structure CH1 and the second channel structure CH2 may be disconnected. According to a method for manufacturing a semiconductor memory according to some example embodiments, the spacer SP1 may be removed and the channel pad 160 may not be substantially removed by a selective etching process. Thus, electrical characteristics between the first channel structure CH1 and the second channel structure CH2 may be improved.

In some example embodiments, the second etching process may use a first gas and a second gas. The first gas may include hydrogen halide. For example, the first gas may include any one of hydrogen bromide (HBr), hydrogen chloride (HCl), hydrogen fluoride (HF), or hydrogen iodide (HI). The second gas may include nitrogen (N₂). The concentration of the first gas may be greater than the concentration of the second gas. The ratio of the first gas to the second gas may be from 2:1 to 4:1. In some example embodiments, the ratio of the first gas to the second gas may be 3:1. The temperature of the second etching process may be about 300 to about 600 degrees Celsius. The pressure of the second etching process may be about 1 to about 40 Torr.

The spacer SP1 may be removed by the second etching process to form the second channel hole CH2_H. The second channel hole CH2_H may include the first through hole PH1, the second through hole PH2, and a portion from which the sacrificial insulating layer 250 has been removed by the first etching process of FIG. 15. An inner side surface of the second channel hole CH2_H may be defined by the first interlayer insulating layer 282, the select gate electrode 270, the upper insulating layer 260, and the sacrificial insulating layer 250. The bottom surface of the second channel hole CH2_H may be defined by the channel pad 160. The inner side (e.g., the inner side surface) and the bottom (e.g., the bottom surface) of the second channel hole CH2_H may include a specific element by the second etching process.

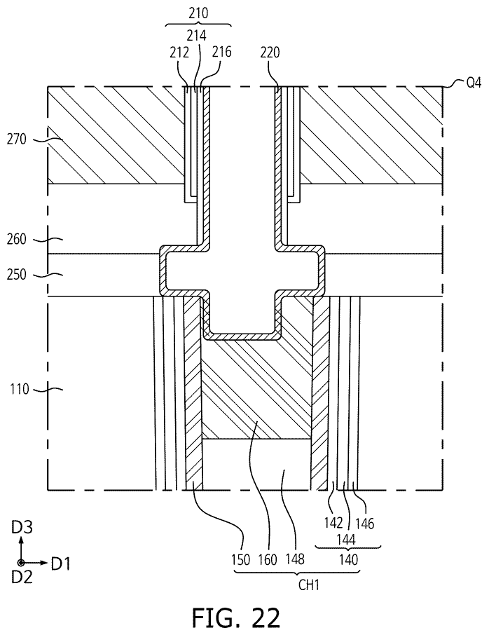

Referring to FIG. 22, the liner film 220 may be formed on the dielectric pattern 210, the upper insulating layer 260, the sacrificial insulating layer 250, and the first channel structure CH1.

For example, the liner film 220 may be formed on the side surface and the bottom surfaces of the third dielectric layer 216 and the second channel hole CH2_H. The liner film 220 may extend along the third dielectric layer 216. The liner film 220 may be formed along a portion of the side of the second channel hole CH2_H on which the dielectric pattern 210 is not disposed, and the bottom (e.g., the bottom surface) of the second channel hole CH2_H.

The liner film 220 may be deposited using an organosilane precursor. The organosilane precursor used for the deposition of the liner film 220 may include at least one of diisopropylaminosilane (DIPAS), diisopropylaminosilane (DIPADS), butylaminosilane (BAS), bistersuric butylaminosilane (BTBAS), dimethylaminosilane (DMAS), bisdimethylaminosilane (BDMAS), tridimethylaminosilane (TDMAS), diethylaminosilane (MEAS), bisdiethylaminosilane (BDEAS), or dipropylaminosilane (DPAS).

The temperature of the process for forming the liner film 220 may be about 450 to about 600 degrees Celsius, and the pressure may be about 0.1 to about 3 Torr. The liner film 220 may be a carbon rich and nitrogen rich silicon layer. For example, the liner film 220 may include silicon carbon nitride (SiCN).

In some example embodiments, the second etching process and the process of forming the liner film 220 may be performed by an in-situ method. That is, the second etching process and the process of forming the liner film 220 may be continuously performed in one chamber. The term “continuously” may herein refer to the processes that are performed without opening the chamber. If the channel pad 160 is exposed to air, an oxide film may be formed on the surface of the channel pad 160. The oxide film may increase a resistance between the channel pad 160 and the second channel structure CH2. On the other hand, if the second etching process and the process of forming the liner film 220 are performed by the in-situ method, formation of the oxide film on the channel pad 160 may be reduced or prevented. Accordingly, resistance between the channel pad 160 and the second channel structure CH2 may decrease.

Referring to FIGS. 2 and 4, the second semiconductor pattern 230 and the filling pattern 240 may be formed on the liner film 220, thereby forming the second channel structure CH2. The second interlayer insulating layer 284 and the upper via 285 may be formed on the first interlayer insulating layer 282. The third interlayer insulating layer 286 and the bit line plug 292 may be formed on the second interlayer insulating layer 284. The bit line 294 may be formed on the bit line plug 292.

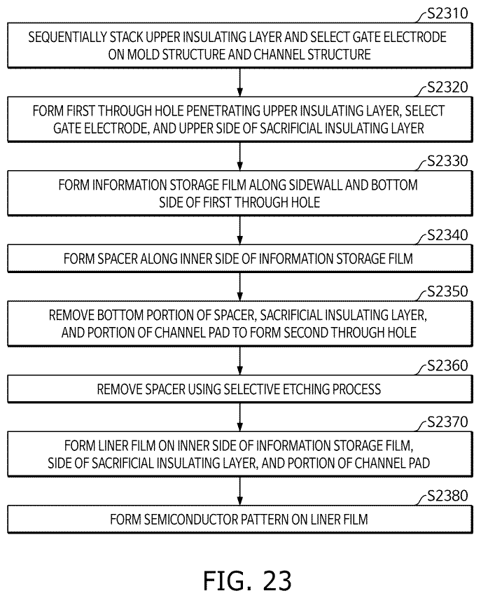

FIG. 23 is a flowchart provided to explain a method for manufacturing a semiconductor memory device according to an example embodiment.

Referring to FIG. 23, the method for manufacturing the semiconductor memory device according to an example embodiment may be initiated by stacking the upper insulating layer and the select gate electrode on the mold structure and the channel structure, at S2310.

The first through hole penetrating through the upper insulating layer, the select gate electrode, and the upper surface of the sacrificial insulating layer in the third direction may be formed, at S2320.

The information storage film may be formed along the side (e.g., the sidewall) and the bottom (e.g., the bottom surface) of the first through hole, at S2330.

The spacer may be formed along an inner side surface of the information storage film, at S2340.

The bottom portion of the spacer, the sacrificial insulating layer, and a portion of the channel pad may be removed to form the second through hole, at S2350.

In some example embodiments, the method may further include, after forming the second through hole at S2350, removing a portion of the sacrificial insulating layer exposed by the second through hole in the first direction. The removing the portion of the sacrificial insulating layer exposed by the second through hole in the first direction may include forming a pre-insulating layer on the spacer and the channel pad exposed by the second through hole, removing a portion of the sacrificial insulating layer in the first and second directions, and removing the pre-insulating layer.

The spacer may be removed using a selective etching process, at S2360. The selective etching process may include using the first gas, and the first gas may have an etch selectivity with respect to the spacer and the channel pad. The selective etching process may further include using the second gas, in which a concentration of the first gas may be greater than a concentration of the second gas, and the first gas may include a halogen element. In some example embodiments, the selective etching process may be a process of removing amorphous silicon.

A liner film may be formed on the inner side surface of the information storage film, the side of the sacrificial insulating layer, and a portion of the channel pad, at S2370. In some example embodiments, removing the spacer at S2360 and forming the liner film at S2370 may be performed by an in-situ method. The liner film may be deposited using an organosilane precursor. The liner film may be deposited in a temperature range of about 450 to about 600 degrees Celsius.

A semiconductor pattern may be formed on the liner film, at S2380. A filling pattern may be formed on the semiconductor pattern.

FIG. 24 is an example block diagram provided to explain an electronic system according to an example embodiment.

Referring to FIG. 24, an electronic system 1000 may include a semiconductor memory device 1100 described with reference to FIGS. 1 to 13, and a controller 1200 electrically connected to the semiconductor memory device 1100. The electronic system 1000 may be a storage device including one or a plurality of semiconductor memory devices 1100 or an electronic device including a storage device. For example, the electronic system 1000 may be a solid state drive device (SSD), a universal serial bus (USB), a computing system, a medical device, or a communication device, which may include one or a plurality of semiconductor memory devices 1100.

For example, the semiconductor memory device 1100 may be the NAND flash memory device described above with reference to FIGS. 1 to 13. The semiconductor memory device 1100 may include a first structure 1100F and a second structure 1100S on the first structure 1100F. The first structure 1100F may be a peripheral circuit structure including a decoder circuit 1110, the page buffer 1120, and the logic circuit 1130. The second structure 1100S may be a memory cell structure including a bit line BL, a common source line CSL, word lines WL, first and second gate upper lines UL1 and UL2, first and second gate lower lines LL1 and LL2, and memory cell strings CSTR between the bit line BL and the common source line CSL.

In the second structure 1100S, each of the memory cell strings CSTR may include lower transistors LT1 and LT2 adjacent to the common source line CSL and upper transistors UT1 and UT2 adjacent to the bit line BL, and a plurality of memory cell transistors MCT disposed between the lower transistors LT1 and LT2 and the upper transistors UT1 and UT2. The number of the lower transistors LT1 and LT2 and the number of the upper transistors UT1 and UT2 may vary according to various example embodiments.

In some example embodiments, the upper transistors UT1 and UT2 may include a string select transistor, and the lower transistors LT1 and LT2 may include a ground select transistor. The gate lower lines LL1 and LL2 each may be gate electrodes of the lower transistors LT1 and LT2. The word lines WL may be gate electrodes of the memory cell transistors MCT, and the gate upper lines UL1 and UL2 may be gate electrodes of the upper transistors UT1 and UT2, respectively.

The common source line CSL, the first and second gate lower lines LL1 and LL2, the word lines WL, and the first and second gate upper lines UL1 and UL2 may be electrically connected to the decoder circuit 1110 through first connection lines 1115 extending from within the first structure 1100F to the second structure 1100S. The bit lines BL may be electrically connected to the page buffer 1120 through second connection wires 1125 extending from within the first structure 1100F to the second structure 1100S.

In the first structure 1100F, the decoder circuit 1110 and the page buffer 1120 may perform a control operation on at least one memory cell transistor selected from among the plurality of memory cell transistors MCT. The decoder circuit 1110 and the page buffer 1120 may be controlled by the logic circuit 1130. The semiconductor memory device 1100 may communicate with the controller 1200 through the input and output pad 1101 electrically connected to the logic circuit 1130. The input and output pad 1101 may be electrically connected to the logic circuit 1130 through an input and output connection wiring 1135 extending from within the first structure 1100F to the second structure 1100S.

The controller 1200 may include a processor 1210, a NAND controller 1220, and a host interface 1230. According to some example embodiments, the electronic system 1000 may include a plurality of semiconductor memory devices 1100, and in this case, the controller 1200 may control the plurality of semiconductor memory devices 1100.

The processor 1210 may control the overall operation of the electronic system 1000 including the controller 1200. The processor 1210 may operate according to desired (or alternatively, predetermined) firmware, and may control the NAND controller 1220 to access the semiconductor memory device 1100. The NAND controller 1220 may include a NAND interface (or controller interface) 1221 that processes communication with the semiconductor memory device 1100. A control command for controlling the semiconductor memory device 1100, data to be written in the memory cell transistors MCT of the semiconductor memory device 1100, data to be read from the memory cell transistors MCT of the semiconductor memory device 1100, etc. may be transmitted through the NAND interface 1221. The host interface 1230 may provide a function of communication between the electronic system 1000 and an external host. Upon receiving a control command from the external host through the host interface 1230, the processor 1210 may control the semiconductor memory device 1100 in response to the control command.

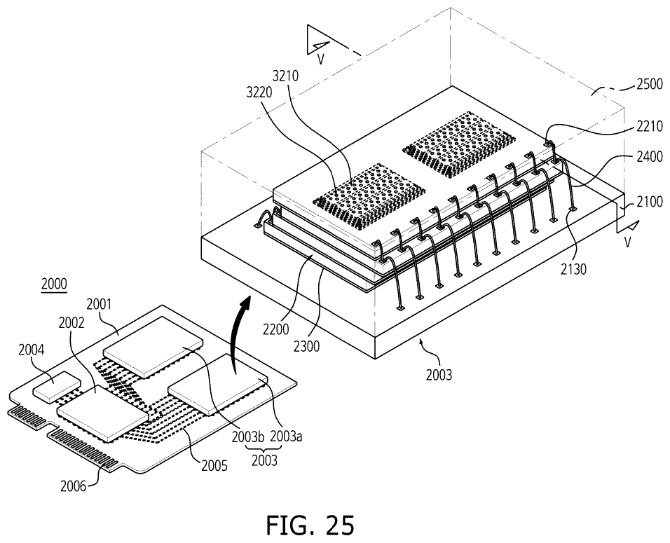

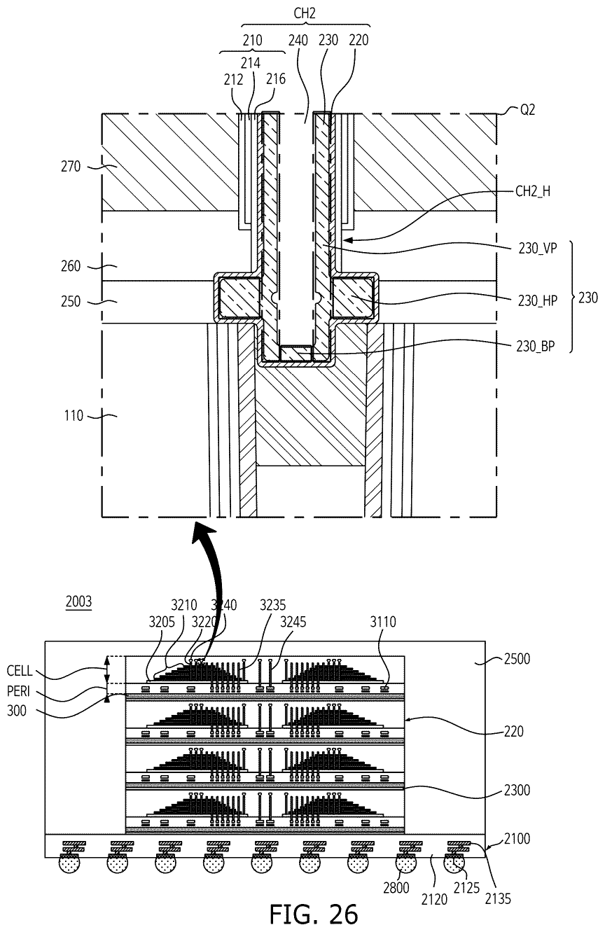

FIG. 25 is an example perspective view illustrating an electronic system including a semiconductor memory device according to an example embodiment. FIG. 26 is a schematic cross-sectional view taken along line V-V of FIG. 25.

Referring to FIG. 25, an electronic system 2000 may include a main substrate 2001, a controller 2002 mounted on the main substrate 2001, one or more semiconductor packages 2003, and a DRAM 2004. The semiconductor package 2003 and the DRAM 2004 may be connected to the controller 2002 by wiring patterns 2005 formed on the main substrate 2001.

The main substrate 2001 may include a connector 2006 including a plurality of pins coupled to the external host. The number and arrangement of the plurality of pins in the connector 2006 may vary according to a communication interface between the electronic system 2000 and the external host. In some example embodiments, the electronic system 2000 may communicate with an external host according to any one of interfaces such as Universal Serial Bus (USB), Peripheral Component Interconnect Express (PCI-Express), Serial Advanced Technology Attachment (SATA), or M-Phy for Universal Flash Storage (UFS). In some example embodiments, the electronic system 2000 may operate by the power supplied from an external host through the connector 2006. The electronic system 2000 may further include a Power Management Integrated Circuit (PMIC) that distributes the power supplied from the external host to the controller 2002 and the semiconductor package 2003.

The main controller 2002 may record data in the semiconductor package 2003 or read data from the semiconductor package 2003, and may improve the operation speed of the electronic system 2000.

The DRAM 2004 may be a buffer memory to alleviate the speed difference between the external host and the semiconductor package 2003 that is a data storage space. The DRAM 2004 included in the electronic system 2000 may also operate as a kind of cache memory, and may also provide a space for temporarily storing data in a control operation for the semiconductor package 2003. If the electronic system 2000 includes the DRAM 2004, in addition to the NAND controller for controlling the semiconductor package 2003, the main controller 2002 may further include a DRAM controller for controlling the DRAM 2004.

The semiconductor package 2003 may include first and second semiconductor packages 2003a and 2003b spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, semiconductor chips 2200 on the package substrate 2100, adhesive layers 2300 disposed on a lower side of each of the semiconductor chips 2200, a connection structure 2400 electrically connecting the semiconductor chips 2200 and the package substrate 2100, and a molding layer 2500 covering the semiconductor chips 2200 and the connection structure 2400 on the package substrate 2100.

The package substrate 2100 may be a printed circuit board including package upper pads 2130. Each of the semiconductor chips 2200 may include an input and output pad 2210. The input and output pad 2210 may correspond to the input and output pad 1101 of FIG. 24. Each of the semiconductor chips 2200 may include metal lines 3210 and channel structures 3220. Each of the semiconductor chips 2200 may include the semiconductor memory device described above with reference to FIGS. 1 to 13.

In some example embodiments, the connection structure 2400 may be a bonding wire electrically connecting the input and output pad 2210 to the package upper pads 2130. Therefore, in each of the first and second semiconductor packages 2003a and 2003b, the semiconductor chips 2200 may be electrically connected to each other with the bonding wire method, and may be electrically connected to the package upper pads 2130 of the package substrate 2100. In some example embodiments, in each of the first and second semiconductor packages 2003a and 2003b, the semiconductor chips 2200 may be electrically connected to each other through a connection structure including through-electrodes (Through Silicon Via, TSV) instead of the bonding wire type connection structure 2400.

In some example embodiments, the main controller 2002 and the semiconductor chips 2200 may be included in one package. In some example embodiments, the main controller 2002 and the semiconductor chips 2200 may be mounted on a separate interposer substrate different from the main substrate 2001, and the main controller 2002 and the semiconductor chips 2200 may be connected to each other through wiring formed on the interposer substrate.

In some example embodiments, the package substrate 2100 may be a printed circuit board. The package substrate 2100 may include a package substrate body portion 2120, the package upper pads 2130 disposed on the upper surface of the package substrate body portion 2120, lower pads 2125 disposed on the lower side of the package substrate body portion 2120 or exposed through the lower side, and internal wires 2135 electrically connecting the upper pads 2130 and the lower pads 2125 inside the package substrate body portion 2120. The upper pads 2130 may be electrically connected to the connection structures 2400. The lower pads 2125 may be connected to the wiring patterns 2005 of the main substrate 2001 of the electronic system 2000 through conductive connections 2800, as illustrated in FIG. 25.

In an electronic system according to some example embodiments, each of the semiconductor chips 2200 may include the semiconductor memory device described above with reference to FIGS. 1 to 13. For example, each of the semiconductor chips 2200 may include the peripheral circuit structure PERI and the cell structure CELL stacked on the peripheral circuit structure PERI. For example, the peripheral circuit structure PERI may include the peripheral circuit substrate 300 and a peripheral wiring 3110 described above with reference to FIGS. 1 to 13. In addition, for example, the cell structure CELL may include a common source line 3205, a gate stack structure 3210 on the common source line 3205, a channel structure 3220 and an isolation structure 3230 penetrating through the gate stacked structure 3210, a bit line 3240 electrically connected to the channel structure 3220, and a gate connection wiring electrically connected to the word line of the gate stack structure 3210.

Each of the semiconductor chips 2200 may include a through wiring 3245 electrically connected to the peripheral wiring 3110 of the peripheral circuit structure PERI and extending into the cell structure CELL. The through wiring 3245 may penetrate through the gate stack structure 3210 and may be further disposed outside the gate stack structure 3210. Each of the semiconductor chips 2200 may further include an input and output connection wiring 3265 electrically connected to the peripheral wiring 3110 of the peripheral circuit structure PERI and extending into a second structure 3200, and the input and output pad 2210 electrically connected to the input and output connection wiring 3265.

Any functional blocks shown in the figures and described above may be implemented in processing circuitry such as hardware including logic circuits, a hardware/software combination such as a processor executing software, or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

Although certain aspects of the present disclosure have been described with reference to the accompanying drawings, those of ordinary skill in the art to which the present disclosure pertains will understand that the present disclosure may be implemented in other specific forms without changing its technical idea or essential features. Therefore, it should be understood that the example embodiments described above are illustrative and non-limiting in all respects.

1. A semiconductor memory device, comprising:
a substrate;
a mold structure including a plurality of mold insulating layers and a plurality of gate electrodes, the plurality of mold insulating layers and the plurality of gate electrodes being alternately stacked on top of each other on the substrate in a first direction;
a first channel structure penetrating through the mold structure and extending in the first direction, the first channel structure including a first semiconductor pattern, a channel pad connected to the first semiconductor pattern, and an information storage film between the first semiconductor pattern and the plurality of gate electrodes;
an upper insulating layer on the mold structure;
a select gate electrode on the upper insulating layer; and
a second channel structure penetrating through the select gate electrode and the upper insulating layer, the second channel structure connected to the first channel structure, wherein
the second channel structure includes
a second semiconductor pattern electrically connected to the channel pad,
a dielectric pattern between the second semiconductor pattern and the select gate electrode, and
a liner film along an outer side surface of the second semiconductor pattern.

2. The semiconductor memory device according to claim 1, wherein
the second semiconductor pattern extends in the first direction, and
a lower portion of the second semiconductor pattern penetrates through at least an upper portion of the channel pad.

3. The semiconductor memory device according to claim 2, wherein a portion of the liner film is between the lower portion of the second semiconductor pattern and the channel pad.

4. The semiconductor memory device according to claim 1, wherein
the second channel structure further includes a filling pattern in a space defined by the second semiconductor pattern, the filling pattern extending in the first direction,
the outer side surface of the second semiconductor pattern is in contact with the liner film, and
an inner side surface of the second semiconductor pattern is in contact with the filling pattern.

5. The semiconductor memory device according to claim 4, wherein the second semiconductor pattern is an integral body.

6. The semiconductor memory device according to claim 1, wherein the second semiconductor pattern includes a vertical portion extending in the first direction and a horizontal portion protruding from the vertical portion in a second direction, the second direction being a horizontal direction intersecting the first direction.

7. The semiconductor memory device according to claim 6, wherein the horizontal portion of the second semiconductor pattern is on an upper surface of the first channel structure.

8. The semiconductor memory device according to claim 6, further comprising:
a sacrificial insulating layer between the mold structure and the upper insulating layer, wherein
the horizontal portion of the second semiconductor pattern overlaps the sacrificial insulating layer in the second direction.

9. The semiconductor memory device according to claim 1, wherein an inner side surface of the dielectric pattern includes a halogen element.

10. The semiconductor memory device according to claim 1, wherein at least a portion of a lower portion of the liner film is along an upper surface of the channel pad.

11. The semiconductor memory device according to claim 10, further comprising:
an etching stop layer on an upper surface of the mold structure; and
a sacrificial insulating layer between the etching stop layer and the upper insulating layer.

12. The semiconductor memory device according to claim 1, further comprising:
a doping pattern in a space defined by the second semiconductor pattern, wherein
the doping pattern is in contact with a lower portion of the second semiconductor pattern.

13. The semiconductor memory device according to claim 12, wherein a distance from an upper surface of the channel pad to an upper surface of the doping pattern is less than a distance from the upper surface of the channel pad to a lower side of the select gate electrode.

14. The semiconductor memory device according to claim 1, wherein at least a portion of the liner film is in contact with the first semiconductor pattern.

15. The semiconductor memory device according to claim 1, further comprising:
an upper isolation pattern penetrating through the select gate electrode.

16. The semiconductor memory device according to claim 1, wherein the liner film includes silicon carbon nitride (SiCN).

17. A semiconductor memory device, comprising:
a peripheral circuit structure; and
a cell structure stacked on the peripheral circuit structure, wherein
the cell structure includes
a substrate,
a mold structure including a plurality of mold insulating layers and a plurality of gate electrodes, the plurality of mold insulating layers and the plurality of gate electrodes being alternately stacked on top of each other on the substrate in a first direction,
a first channel structure penetrating through the mold structure and extending in the first direction, the first channel structure including a first semiconductor pattern, a channel pad on the first semiconductor pattern, and an information storage film between the first semiconductor pattern and the plurality of gate electrodes,
an upper insulating layer on the mold structure,
a select gate electrode on the upper insulating layer,
a second channel structure penetrating through the select gate electrode and the upper insulating layer, the second channel structure connected to the first channel structure,
a bit line plug connected to the second channel structure, and
a bit line connected to the bit line plug and extending in a second direction, the second direction being a horizontal direction intersecting the first direction, and the second channel structure includes,
a second semiconductor pattern electrically connected to the channel pad;
a dielectric pattern between the second semiconductor pattern and the select gate electrode; and
a liner film along an outer side surface of the second semiconductor pattern.

18. The semiconductor memory device according to claim 17, wherein at least a portion of the liner film is in contact with the channel pad.

19. The semiconductor memory device according to claim 18, wherein
the second semiconductor pattern includes a vertical portion extending in the first direction, and a horizontal portion protruding from the vertical portion in the second direction, and
the horizontal portion of the second semiconductor pattern is on an upper surface of the first channel structure.

20. An electronic system, comprising:
a main substrate;
a semiconductor memory device on the main substrate, the semiconductor memory device including a peripheral circuit structure and a cell structure stacked on the peripheral circuit structure; and
a controller on the main substrate and electrically connected to the semiconductor memory device, wherein
the cell structure includes
a substrate,
a mold structure including a plurality of mold insulating layers and a plurality of gate electrodes, the plurality of mold insulating layers and the plurality of gate electrodes being alternately stacked on top of each other on the substrate in a first direction,
a first channel structure penetrating through the mold structure and extending in the first direction, the first channel structure including a first semiconductor pattern, a channel pad on the first semiconductor pattern, and an information storage film between the first semiconductor pattern and the plurality of gate electrodes,
an upper insulating layer on the mold structure,
a select gate electrode on the upper insulating layer, and
a second channel structure penetrating through the select gate electrode and the upper insulating layer, the second channel structure connected to the first channel structure, and
the second channel structure includes,
a second semiconductor pattern electrically connected to the channel pad,
a dielectric pattern between the second semiconductor pattern and the select gate electrode, and
a liner film along an outer side surface of the second semiconductor pattern.

21.-29. (canceled)
